(19) United States
(12) Patent Application Publication
(10) Pub. No.: US 2002/0149417 A1
(43) Pub. Date: Oct. 17, 2002

(54) Controller for driving electric vehicle

(75) Inventors: Masayoshi Kumano, Tokyo (JP); Susumu Shikata, Tokyo (JP); Takafumi Maruyama, Tokyo (JP)

Correspondence Address: SUGHRUE MION ZINN MACPEAK & SEAS, PLLC, 2100 Pennsylvania Avenue, NW, Washington, DC, 20037-3213, US

(73) Assignee: MITSUBISHI DENKI KABUSHIKI KAISHA

(21) Appl. No.: 09/961,321

(22) Filed: Sep. 25, 2001

(30) Foreign Application Priority Data
Apr. 13, 2001 (JP) 2001-115301

(51) Int. Cl. H03B 1/00

(52) U.S. Cl. 327/552

(57) ABSTRACT

The present invention provides a controller for driving an electric vehicle including a small filter having sufficient attenuation characteristics in order to avoid the adverse influence of the higher harmonic component contained in the return wire current flowing through a rail exerted on the safety equipment for railway or the like provided therein. In a controller for driving an electric vehicle including an inverter 6 supplied with the electric power through a D.C. filter 5, in the D.C. filter 5, two reactors 51a and 51b having the magnetic coupling are connected in series to ensure effectively an inductance, to realize miniaturization and also to make the near-place installation possible. A first capacitor 52a is connected between output terminals, and to the series connection point of the two reactors, a third reactor 53 having an inductance value roughly equal to the mutual inductance thereof and a second capacitor 52b which are connected in series are connected to cancel the negative equivalent inductance provided by the magnetic coupling to prevent the adverse influence of the magnetic coupling, whereby the two-stage filter characteristics are effectively utilized and a substantial attenuation of the higher harmonic components is realized.

This application is based on Application No. 2001-115301, filed in Japan on Apr. 13, 2001, the contents of which are hereby incorporated by reference.

### BACKGROUND OF THE INVENTION

1. Field of the Invention

The present invention relates in general to a controller for driving an electric vehicle which is supplied with electric power from a feeder line to be driven. More has a D.C. filter for preventing the higher harmonic currents from flowing thereinto or flowing out therefrom.

2. Description of the Related Art

FIG. 6 is a schematic block diagram showing the configration of a conventional controller for driving an electric vehicle shown in JAPANESE PATENT APPLICATION LAID-OPEN KOHO No. 188803 of 2000, for example. In FIG. 6, the D.C. electric power which is applied across a feeder line (stringing) 1 and a rail 2 is collected by a collector 3 to be inputted to an inverter 6 through a breaker 4, and a reactor 51 and a capacitor 52 constituting a D.C. filter 50. The inverter 6 is adapted to convert the D.C. electric power inputted thereto into A.C. electric power which has been controlled in a voltage-variable and frequency-variable manner to supply the A.C. electric power thus obtained to an A.C. motor 7 for driving a vehicle. In this case, an input voltage to the inverter 6 is smoothed by the capacitor 52, and also the influence of the higher harmonics generated by the switching operation which is exerted on the power source side is prevented by the reactor 51.

In the conventional controller for driving an electric vehicle employing the electric power converter as described above, the higher harmonic components contained in the return wire current which is caused to flow through the rail 2 as the return route to the substation or the like as the power source may cause malfunction of the safety equipment for the railway such as the grade crossing controllers and the ringers provided therein in some cases. In this way, the higher harmonic components may adversely affect the safety equipment for the railway. In order to avoid such an adverse influence, an L-C D.C. filter 50 constituted of the reactor 51 and the capacitor 52 is provided. However, the allowable limit value of the higher harmonic components in the return wire current, for preventing the malfunction is very small, and in particular, in the vicinity of several hundreds Hz, must be reduced to the level equal to or lower than 1/10000 of the D.C. component equal to or lower than 50 MA. On the other hand, the higher harmonics generated on the side of the inverter 6 can not be excessively reduced due to various restrictions, so that in order to ensure sufficient attenuation characteristics of the current higher harmonics, a filter having a large capacity is required, resulting in an increase in size and weight. As a result, there arises a problem that the on-board mounting thereof becomes difficult.

### SUMMARY OF THE INVENTION

In the light of the foregoing, the present invention has been made in order to solve the above-mentioned problems in the prior art, and it is therefore an object of the present invention to obtain a controller for driving an electric vehicle which is capable of ensuring sufficient attenuation characteristics of the higher harmonic components in the return wire current.

Bearing the above object in mind, according to the present invention, there is provided a controller for driving an electric vehicle including an inverter to which D.C. electric power from a feeder line is inputted through a D.C. filter and which supplies an A.C. motor with A.C. electric power which has been controlled in the variable-voltage and variable-frequency manner, wherein the D.C. filter is constituted by a first and a second reactors which are connected in series between positive input and output terminals and which have the magnetic coupling, a first capacitor which is provided between output terminals, and serial-connected third reactor and second capacitor which are provided between the series connection point of the first and second reactors and a negative side terminal.

In a preferred form of the present invention, the third reactor has an inductance value which is roughly equal to the mutual inductance value of the first and second reactors.

In another preferred form of the present invention, a resistor for the damping is provided in the series circuit of the third reactor and the second capacitor.

In a further preferred form of the present invention, instead of the first and second reactors which are connected in series, a reactor with an intermediate tap is employed.

In a yet further preferred form of the present invention, an inductance of the wiring cable is employed for a part or all of the third reactor.

### BRIEF DESCRIPTION OF THE DRAWINGS

FIG. 1 is a schematic diagram showing the controller for driving an electric vehicle according to a first embodiment of the present invention;

FIG. 2 is an equivalent circuit diagram of a filter reactor shown in FIG. 1;

FIG. 3 is a graphical representation explaining the transfer characteristics of a D.C. filter shown in FIG. 1;

FIG. 4 is a circuit diagram showing the configuration of a filter part of a controller for driving an electric vehicle according to a second embodiment of the present invention;

FIG. 5 is a circuit diagram showing the configuration of a filter part of a controller for driving an electric vehicle according to a third embodiment of the present invention; and

FIG. 6 is a schematic diagram showing the conventional controller for driving an electric vehicle.

### DESCRIPTION OF THE PREFERRED EMBODIMENTS

(First Embodiment)

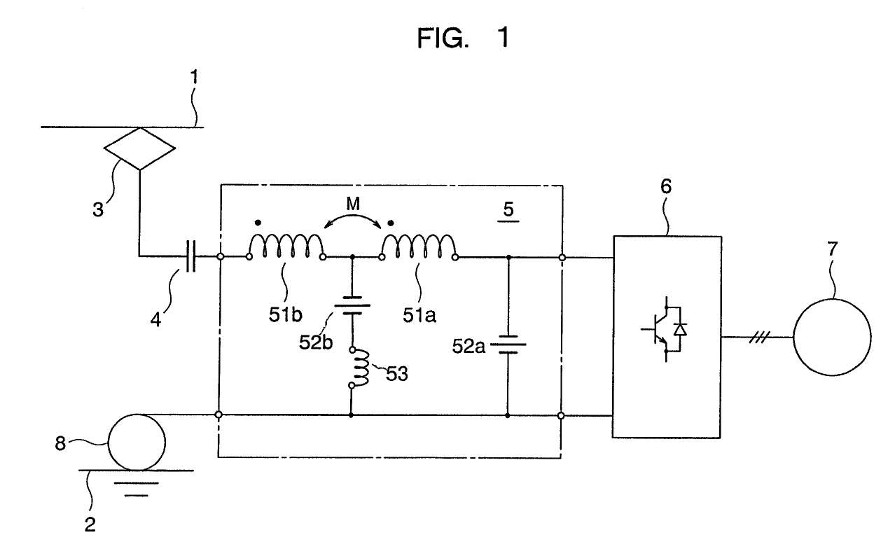

FIG. 1 is a schematic diagram showing the controller for driving an electric vehicle according to a first embodiment of the present invention. In FIG. 1, reference numeral 1 designates a feeder line (a stringing or a third rail), reference numeral 2 designates a rail, reference numeral 3 designates a collector, reference numeral 4 designates a breaker, reference numeral 5 designates a D.C. filter, a reference numeral 6 designates an inverter, reference numeral 7 designates an A.C. motor (an induction motor or a synchronous motor), and reference numeral 8 designates a wheel. The D.C. electric power which is applied across the feeder line 1 and the rail 2 is collected by the collector 3 to be inputted to the inverter 6 through the breaker 4 and the D.C. filter 5. The inverter 6 converts the D.C. electric power inputted thereto into the A.C. electric power which has been controlled in the variable-voltage and variable-frequency manner to input the A.C. electric power thus obtained to the A.C. motor 7 for driving the vehicle.

Now, in the D.C. filter 5, the series two-stages L-C filter is constituted by two reactors 51a and 51b which are provided in such a way as to be close to each other to be connected in series between positive input and output terminals and which have the magnetic coupling, and two capacitors 52a and 52b connected in parallel. Also, a third reactor 53 is connected in series therewith in order to cancel the mutual inductance between the above-mentioned two reactors. That is, the third reactor 53 and the second capacitor 52b connected in series are provided between the series connection point of the reactors 51a and 51b, and a negative side terminal.

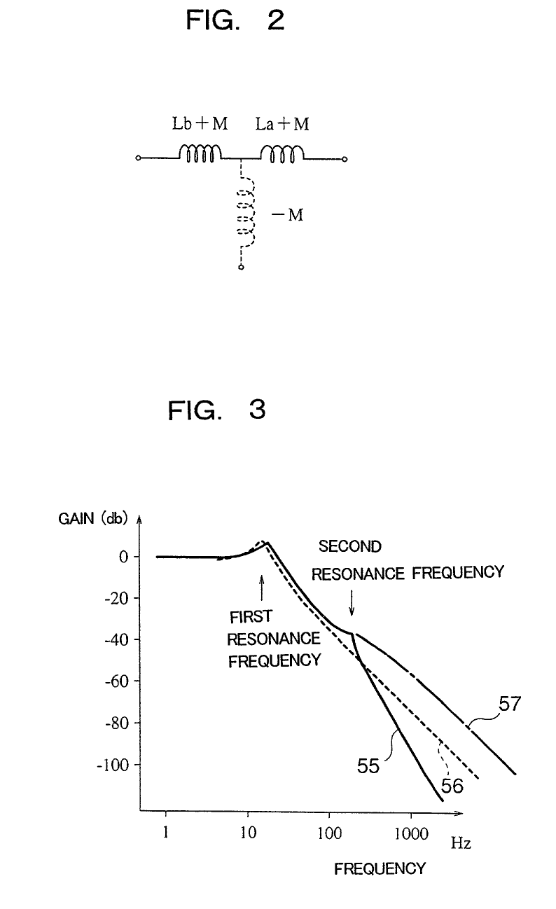

Since the D.C. main current is caused to flow through the reactors 51a and 51b, the air-core reactors which are forcedly cooled are employed therefor. Then, the two reactors are provided in such a way as to be close to each other, whereby the large inductance, though each of the two reactors is of a small size, can be obtained by utilizing the mutual magnetic coupling. That is, when the self-inductances are La and Lb, respectively, and the mutual inductance is M (M=k\sqrt{La×Lb}), as shown in FIG. 2 as the equivalent circuit diagram of the two reactors, the equivalent inductances of the reactors become La+M, and Lb+M, respectively. In addition, as for the forced cooling mechanism, the one common to the two reactors can be readily utilized, and hence the miniaturization can be realized.

However, on the other hand, while it is considered that the inductance of −M is equivalently connected to the connection junction of the two reactors, and hence in the higher frequency region, this inductance intends to impede the bypass operation by the capacitor 52b shown in FIG. 1 to degrade the filter characteristics, the third reactor 53 having the inductance value equal to the mutual inductance M is installed, whereby the equivalent inductance −M provided by the above-mentioned coupling is cancelled, and hence this bypass circuit becomes equivalent to only the capacitor 52b. By the way, since the current which is caused to flow through this bypass circuit is normally so small as to be equal to or smaller than 1/10 of the main current which is caused to flow through the two reactors 52a and 52b, though the value of the inductance is M, the third reactor 53 becomes relatively small and hence the cooling therefor also becomes easy. In addition, the inductance of the wiring can also be utilized for a part or all of this inductance value.

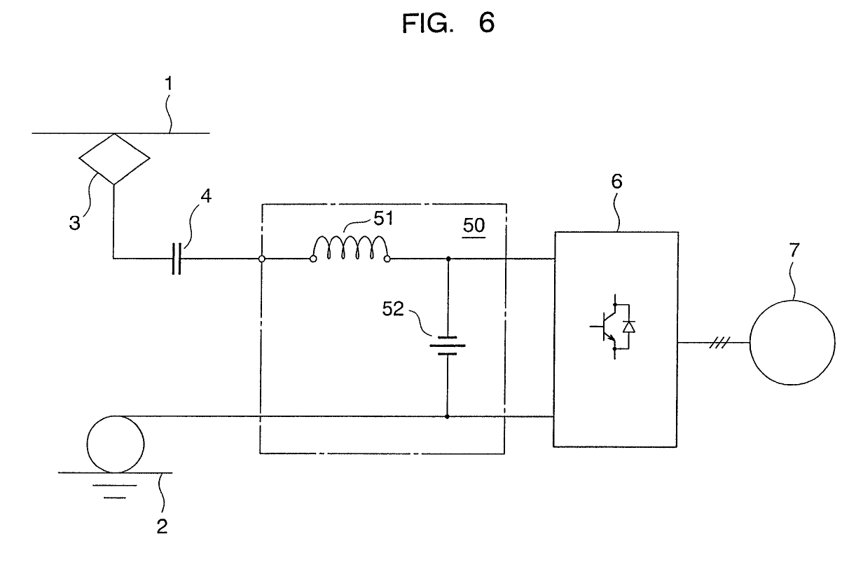

FIG. 3 shows one example of the current transfer characteristics of the D.C. filter 5 when viewed from the side of the inverter 6. A curve 55 shows the characteristics of the filter 5 of the present invention shown in FIG. 1, a curve 56 shows the characteristics of the conventional filter 50 shown in FIG. 6, and a curve 57 shows the characteristics in the case where the third reactor 53 is not provided in the filter 5 of the present invention shown in FIG. 1. In FIG. 3, the conventional characteristic curve 56 attenuates at the rate of −40 db/dec. in the range of equal to or higher than a first resonance frequency, whereas the characteristic curve 55 according to the present invention shows the characteristics of the two-stages filter in which the curve 55 attenuates at the rate of −80 db/dec. in the range of equal to or higher than a second resonance frequency, and hence the characteristics in the higher frequency region are improved. In this connection, the characteristic curve 57 in the case where the third reactor 53 is not provided is inferior to the conventional one-stage filter characteristics 56.

(Second Embodiment)

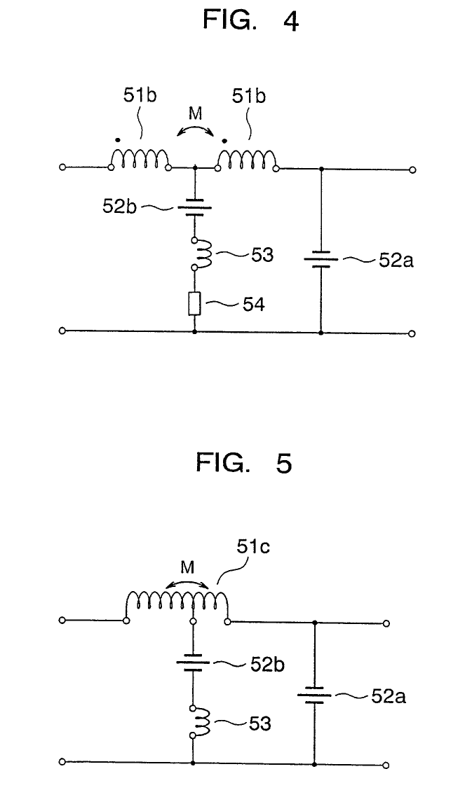

FIG. 4 is a circuit diagram showing the configuration of a D.C. filter in a controller for driving an electric vehicle according to a second embodiment of the present invention. A resistor 54 for the damping is provided in the series circuit of the third reactor 53 and a second capacitor 52b in order to suppress the rising of the characteristics in the second resonance point shown in FIG. 3.

(Third Embodiment)

FIG. 5 is a circuit diagram showing the configuration of a D.C. filter in a controller for driving an electric vehicle according to a third embodiment of the present invention. Instead of the two reactors 51a and 51b connected in series and shown in FIG. 1, a reactor 51c having an intermediate tap is employed to realize the miniaturization. The operation thereof is the same as that of FIG. 1.

As set forth hereinabove, according to the present invention, a D.C. filter is constituted of first and second reactors which are connected in series between positive input and output terminals and which have the magnetic coupling, a first capacitor which is provided between output terminals, and serial-connected third reactor and second capacitor which are provided between the series connection point of the first and second reactors and a negative side terminal. As a result, it is possible to ensure the sufficient attenuation characteristics of the higher harmonic components in the return wire current.

In addition, the inductance value of the third reactor is made roughly equal to the value of the mutual inductance of the first and second reactors, whereby the equivalent inductance provided by the coupling of the first and second reactors can be cancelled and also a bypass circuit can be made equivalent to only the capacitor.

In addition, a resistor is provided between the third reactor and the second capacitor, whereby the role of the damping is performed, and also the rising of the gain vs. frequency characteristics in the second resonance point of the D.C. filter can be suppressed.

In addition, instead of the first and second reactors connected in series, a reactor with an intermediate tap is employed, whereby the miniaturization can be realized.

Moreover, a part or all of the third reactor can be constituted by using an inductance of the wiring cable.

What is claimed is:

1. A controller for driving an electric vehicle including an inverter to which D.C. electric power from a feeder line is inputted through a D.C. filter and which supplies an A.C. motor with A.C. electric power which has been controlled in the variable-voltage and variable-frequency manner,
wherein said D.C. filter is constituted by a first and a second reactors which are connected in series between positive input and output terminals and which have the magnetic coupling, a first capacitor which is provided between output terminals, and serial-connected third reactor and second capacitor which are provided between the series connection point of said first and second reactors and a negative side terminal.

2 The controller for driving an electric vehicle according to claim 1, wherein said third reactor has an inductance value which is roughly equal to the mutual inductance value of said first and second reactors.

3 The controller for driving an electric vehicle according to claim 1, wherein a resistor for the damping is provided in the series circuit of said third reactor and second capacitor.

4 The controller for driving an electric vehicle according to claim 1, wherein instead of said first and second reactors which are connected in series, a reactor with an intermediate tap is employed.

5 The controller for driving an electric vehicle according to claim 1, wherein an inductance of the wiring cable is employed for a part or all of said third reactor.
